(19) United States
(12) Patent Application Publication
(10) Pub. No.: US 2023/0403766 A1
(43) Pub. Date: Dec. 14, 2023

(54) HEATING DEVICE FOR TRACKING RESONANCE FREQUENCY

(71) Applicant: SAMSUNG ELECTRONICS CO., LTD., Suwon-si (JP)

(72) Inventors: Nobuharu NISHIKOORI, Yokohama-shi (JP); Masayuki OTAWARA, Yokohama-shi (JP); Tomoyuki KANAGAWA, Yokohama-shi (JP); Masashi SASAGAWA, Yokohama-shi (JP); Masaki ONO, Yokohama-shi (JP); Yutaka YAGI, Yokohama-shi (JP); Taro YOSHIDA, Yokohama-shi (JP)

(21) Appl. No.: 18/238,396

(22) Filed: Aug. 25, 2023

Related U.S. Application Data
(63) Continuation of application No. PCT/KR2022/002382, filed on Feb. 17, 2022.

(30) Foreign Application Priority Data
Feb. 26, 2021 (JP) 2021-029403

(51) Int. Cl. H05B 6/06; H05B 6/12

(52) U.S. Cl. CPC H05B 6/062; H05B 6/1209

(57) ABSTRACT

A heating device for tracking a resonance frequency includes a heating coil for heating a cooking appliance, a parallel resonance circuit including an inductor including the heating coil and a resonance capacitor resonating with the inductor, an inverter unit for supplying power to the parallel resonance circuit, a first current sensor for detecting an output current supplied from the inverter unit to the parallel resonance circuit, and a processor for controlling a driving frequency of the inverter unit so that a peak value of the output current detected by the first current sensor is smaller than a predetermined first threshold value.

### CROSS-REFERENCE TO RELATED APPLICATIONS

This application is a continuation application, claiming priority under § 365(c), of International Application No. PCT/KR2022/002382, filed on Feb. 17, 2022, which is based on and claims the benefit of Japanese patent application number 2021-029403 filed on Feb. 26, 2021, in the Japan Patent Office, the disclosures of which are incorporated by reference herein in their entireties.

### BACKGROUND

Embodiments of the disclosure relate to an induction heating home appliance that controls a driving frequency of a heating device to track a resonance frequency of the heating device even when the resonance frequency of the heating device changes due to a change in the driving frequency made by the heating device, and an operation method of the induction heating home appliance.

Detecting the phase of the output voltage of the inverter while heating the object to be heated is difficult, and thus the driving frequency of the inverter device, which is a heating device, is not changed during a heating operation. In this case, when the object to be heated moves during heating and accordingly a resonance point of the inverter device changes, the driving frequency of the inverter deviates from the resonance frequency and thus the efficiency decreases.

In a heating device according to the disclosure, an inverter current is reduced while a driving frequency is tracking a resonance frequency for a current flowing in a heating coil during a heating operation, so that the heating device operates efficiently.

### SUMMARY

According to an aspect of the disclosure, a heating device includes a heating coil for heating a cooking appliance, a parallel resonance circuit including an inductor including the heating coil and a resonance capacitor resonating with the inductor, an inverter unit for supplying power to the parallel resonance circuit, a first current sensor for detecting an output current supplied from the inverter unit to the parallel resonance circuit, and a controller for controlling a driving frequency of the inverter unit so that a peak value of the output current detected by the first current sensor is smaller than a predetermined first threshold value.

According to another aspect of the disclosure, a method, performed by a heating device, of tracking a resonance frequency includes supplying power to a parallel resonance circuit including an inductor including a heating coil for heating a cooking appliance and a resonance capacitor resonating with the inductor, wherein the supplying is performed by an inverter unit included in the heating device, detecting an output current supplied from the inverter unit to the parallel resonance circuit, wherein the detecting is performed by a first current sensor included in the heating device, and controlling a driving frequency of the inverter unit so that a peak value of the output current detected by the first current sensor is smaller than a predetermined first threshold value, wherein the controlling is performed by a controller included in the heating device.

According to the disclosure, even when a parallel resonance frequency fluctuates due to a change in the position of a cooking appliance placed on a heating device, the heating device may control the driving frequency of an inverter to automatically track the parallel resonance frequency.

According to the disclosure, because the driving frequency of the inverter may be controlled to track the parallel resonant frequency, the heating device may reduce an inverter current compared to a current flowing in a heating coil during a heating operation of the heating device.

### DESCRIPTION OF DRAWINGS

FIG. 1 is a block diagram of a function of a heating device according to an embodiment of the disclosure.

FIGS. 2A and 2B are diagrams for explaining cooking systems according to an embodiment of the disclosure.

FIGS. 3A and 3B are detailed diagrams of a heating device according to an embodiment of the disclosure.

FIG. 4 is a graph showing an example of frequency-impedance characteristics of a parallel resonance circuit 20, according to an embodiment of the disclosure.

FIG. 5 illustrates graphs showing the waveform of an inverter voltage and the waveform of a current flowing in a parallel resonance circuit, according to an embodiment of the disclosure.

FIG. 6 is a graph illustrating alternating current (AC) interpretation of branch currents I1 and I2 and an inverter current I3 of a parallel resonance circuit around a resonance frequency fo, according to an embodiment of the disclosure.

FIG. 7A is a diagram illustrating waveforms of an inverter voltage Vo and currents I1, I2, and I3 of a parallel resonance circuit when the effective value of the inverter voltage Vo is large, according to an embodiment of the disclosure.

FIG. 7B is a diagram illustrating waveforms of the inverter voltage Vo and the currents I1, I2, and I3 of a parallel resonance circuit when the effective value of the inverter voltage Vo is small, according to an embodiment of the disclosure.

FIG. 8 is a table illustrating correlations with a peak current flowing in a parallel resonance circuit when the effective value of an output voltage of an inverter circuit is large and when the effective value of the output voltage of the inverter circuit is small, according to an embodiment of the disclosure.

FIG. 9 is a circuit diagram of a heating device including a second current sensor in a parallel resonance circuit, according to an embodiment of the disclosure.

FIG. 10 is a graph showing changes in the branch currents I1 and I2 and the inverter current I3 of the parallel resonance circuit 20 with respect to driving frequency on the horizontal axis, in the circuit diagram of FIG. 8, according to an embodiment of the disclosure.

FIG. 11 is a circuit diagram of a heating device in which a first current sensor is installed in a first circuit and a second current sensor is installed in a second circuit, according to an embodiment of the disclosure.

FIG. 12 is a graph showing changes in the inverter voltage Vo and the branch currents I1 and I2 and the inverter current I3 of the parallel resonance circuit 20 with respect to time on the horizontal axis, in the circuit diagram of FIG. 11, according to an embodiment of the disclosure.

FIG. 13 is a circuit diagram of a heating device 2000b including a half-bridge inverter circuit, according to an embodiment of the disclosure.

FIG. 14A is a circuit diagram of a heating device 2000c including a parallel resonance circuit, according to an embodiment of the disclosure.

FIG. 14B is a circuit diagram of a heating device 2000d including a parallel resonance circuit, according to another embodiment of the disclosure.

FIG. 15 is a circuit diagram of a heating device 2000 including a parallel resonance circuit, when an input voltage of an inverter circuit 1 varies, according to an embodiment of the disclosure.

FIG. 16 is a flowchart of a method of controlling a heating device, according to an embodiment of the disclosure.

FIG. 17 is a flowchart of a method of controlling a heating device, according to another embodiment of the disclosure.

### DETAILED DESCRIPTION

According to an embodiment of the disclosure, a heating device includes a heating coil for heating a cooking appliance, a parallel resonance circuit including an inductor including the heating coil and a resonance capacitor resonating with the inductor, an inverter unit for supplying power to the parallel resonance circuit, a first current sensor for detecting an output current supplied from the inverter unit to the parallel resonance circuit, and a controller for controlling a driving frequency of the inverter unit to track a resonance frequency so that a peak value of the output current detected by the first current sensor is smaller than a predetermined first threshold value.

The controller may control the driving frequency of the inverter unit in a direction in which a slope of the output current is decreased compared to a change in the driving frequency of the inverter unit.

The heating device may further include an inductor filter for filtering a square wave voltage output from the inverter unit into a sine wave shape, between the inverter unit and the parallel resonance circuit.

The controller may control an input voltage of the inverter unit according to a set output heat amount of the heating coil.

Based on a determination that an effective value of an output voltage of the inverter unit is greater than a predetermined value, the controller may control the driving frequency of the inverter unit so that the peak value of the output current detected by the first current sensor is smaller than the predetermined first threshold value.

The heating device may further include, based on a determination that the effective value of the output voltage of the inverter unit is less than a predetermined value, a second current sensor for detecting a current flowing in the parallel resonance circuit, and the controller may control the driving frequency of the inverter unit to decrease based on a determination that the peak value of the output current detected by the first current sensor is equal to or greater than the predetermined first threshold value, and may control the driving frequency of the inverter unit to increase based on a determination that a peak value of a current detected by the second current sensor is greater than a predetermined second threshold value.

An inductor filter may not be included between the inverter unit and the parallel resonance circuit.

The second current sensor may detect a current flowing in the inductor including the heating coil in the parallel resonance circuit.

The second current sensor may detect a current flowing in the resonance capacitor in the parallel resonance circuit.

The controller may control the driving frequency of the inverter unit so that a peak value of a current flowing in a circuit including the heating coil and a peak value of a current flowing in a circuit including the resonance capacitor are within a predetermined error value.

Based on a determination that a resonance frequency of the parallel resonance circuit changes by the controller controlling the driving frequency of the inverter unit so that the peak value of the output current detected by the first current sensor is less than the predetermined first threshold value, the controller may control the driving frequency of the inverter unit to track the resonance frequency of the parallel resonance circuit.

The resonance frequency of the parallel resonance circuit may vary due to a change in the position of the cooking appliance placed on the heating device.

A total impedance of the parallel resonance circuit may be greater than an impedance of the circuit including the heating coil and may be greater than an impedance of the circuit including the resonance capacitor.

The controller may control the driving frequency of the inverter unit in a state in which an effective value of input power of the inverter unit is fixed.

According to an embodiment of the disclosure, a method, performed by a heating device, of tracking a resonance frequency includes supplying power to a parallel resonance circuit including an inductor including a heating coil for heating a cooking appliance and a resonance capacitor resonating with the inductor, wherein the supplying is performed by an inverter unit included in the heating device, detecting an output current supplied from the inverter unit to the parallel resonance circuit, wherein the detecting is performed by a first current sensor included in the heating device, and controlling a driving frequency of the inverter unit so that a peak value of the output current detected by the first current sensor is smaller than a predetermined first threshold value, wherein the controlling is performed by a controller included in the heating device.

Hereinafter, the terms used in the specification will be briefly described, and then the disclosure will be described in detail.

Although general terms widely used at present were selected for describing the disclosure in consideration of the functions thereof, these general terms may vary according to intentions of one of ordinary skill in the art, case precedents, the advent of new technologies, and the like. Terms arbitrarily selected by the applicant of the disclosure may also be used in a specific case. In this case, their meanings need to be given in the detailed description of an embodiment of the disclosure. Hence, the terms must be defined based on their meanings and the contents of the entire specification, not by simply stating the terms.

The terms “comprises” and/or “comprising” or “includes” and/or “including” used herein specify the presence of stated elements, but do not preclude the presence or addition of one or more other elements. The terms “unit”, “-er (-or)”, and “module” when used in this specification refers to a unit in which at least one function or operation is performed, and may be implemented as hardware, software, or a combination of hardware and software.

Embodiments of the disclosure are described in detail herein with reference to the accompanying drawings so that this disclosure may be easily performed by one of ordinary skill in the art to which the disclosure pertains. Embodiments of the disclosure may, however, be embodied in many different forms and should not be construed as being limited to the embodiments set forth herein. In the drawings, parts irrelevant to the description are omitted for simplicity of explanation, and like numbers refer to like elements throughout.

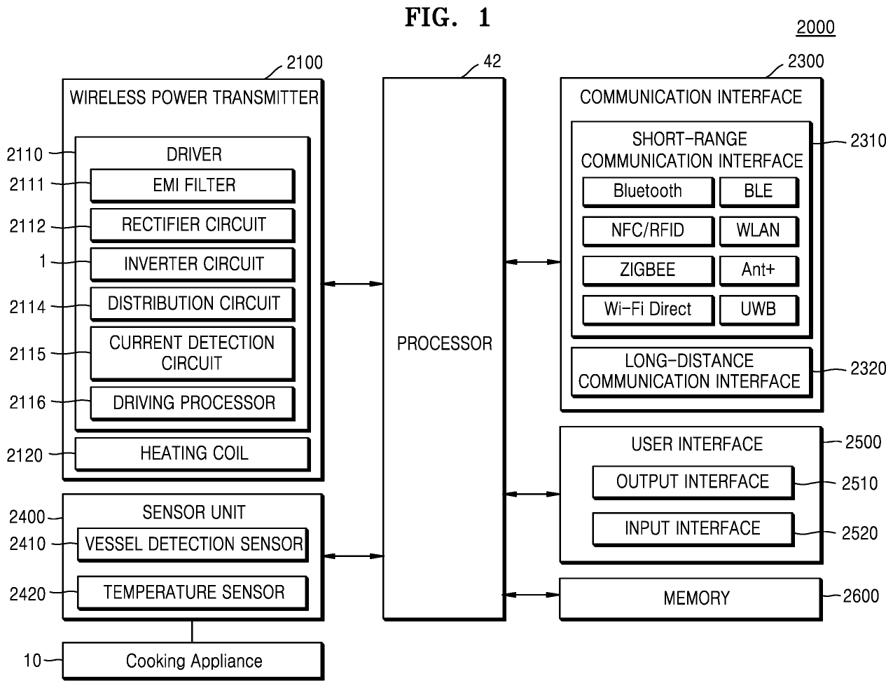

FIG. 1 is a block diagram of a function of a heating device according to an embodiment of the disclosure.

Referring to FIG. 1, a heating device 2000 according to an embodiment of the disclosure may include a wireless power transmitter 2100, a processor 42, a communication interface 2300, a sensor unit 2400, a user interface 2500, and a memory 2600. However, not all of the illustrated components are essential. The heating device 2000 may be implemented by more or less components than those illustrated in FIG. 1.

Throughout the disclosure, the heating device 2000 mainly denotes an induction heating device. However, the heating device 2000 according to the disclosure is not necessarily limited to the induction heating device, and the heating device 2000 according to the disclosure may be used in any application that operates a heating coil by employing a parallel resonance circuit.

The aforementioned components will now be described in detail.

The wireless power transmitter 2100 may include, but is not limited to, a driver 2110 and a heating coil 2120. The heating coil 2120 may be referred to as an operating coil. The driver 2110 may receive power from an external source, and may supply current to the heating coil 2120 according to a driving control signal of the processor 42. The driver 2110 may include, but is not limited to, an electro magnetic interference (EMI) filter 2111, a rectifier circuit 2112, an inverter circuit 1, a distribution circuit 2114, a current detection circuit 2115, and a driving processor 2116.

The EMI filter 2111 may block high-frequency noise included in alternating current (AC) power supplied from the external source, and may transmit an AC voltage and an AC current of a predetermined frequency (e.g., 50 Hz or 60 Hz). A fuse and a relay may be provided between the EMI filter 2111 and the external source in order to block overcurrent. AC power of which high-frequency noise has been blocked by the EMI filter 2111 is supplied to the rectifier circuit 2112.

The rectifier circuit 2112 may convert the AC power into direct current (DC) power. For example, the rectifier circuit 2112 may convert an AC voltage whose magnitude and polarity (positive voltage or negative voltage) change over time into a DC voltage whose magnitude and polarity are constant, and may convert an AC current whose magnitude and polarity (positive current or negative current) change over time into a DC current having a constant magnitude. The rectifier circuit 2112 may include a bridge diode. For example, the rectifier circuit 2112 may include four diodes. The bridge diode may convert an AC voltage whose polarity changes over time into a positive voltage whose polarity is constant, and may convert an AC current whose direction changes over time into a positive current whose direction is constant. The rectifier circuit 2112 may include a DC link capacitor. The DC link capacitor may convert a positive voltage whose magnitude changes with time into a DC voltage having a constant magnitude.

The inverter circuit 1 may include a switching circuit that supplies or blocks a driving current to or from the heating coil 2120, and a resonance circuit that causes resonance together with the heating coil 2120. According to an embodiment of the disclosure, the resonance circuit may be a parallel resonance circuit. The switching circuit may include a first switch and a second switch. The first switch and the second switch may be connected in series between a plus line and a minus line output by the rectifier circuit 2112. The first switch and the second switch may be turned on or off according to a driving control signal of the driving processor 2116. The first switch and the second switch are switch devices, and may include, but are not limited to, transistors, field effect transistors (FETs), and insulated gate bipolar mode transistors (IGBTs). The switching circuit may further include an arm having a third switch and a fourth switch.

The inverter circuit 1 may control a current that is supplied to the heating coil 2120. For example, the magnitude and direction of the current flowing in the heating coil 2120 may change according to turning on/off of the first switch and the second switch included in the inverter circuit 1. In this case, an AC current may be supplied to the heating coil 2120. An AC current in the form of a sine wave is supplied to the heating coil 2120 according to the switching operations of the first switch and the second switch. The longer respective switching periods of the first switch and the second switch (e.g., the smaller respective switching frequencies of the first switch and the second switch are), the larger the current supplied to the heating coil 2120 may be, and the larger the intensity of a magnetic field output by the heating coil 2120 (output of the heating device 2000) may be.

When the heating device 2000 includes a plurality of heating coils 2120, the driver 2110 may include the distribution circuit 2114. The distribution circuit 2114 may include a plurality of switches for transmitting or blocking currents that are supplied to the plurality of heating coils 2120, and the plurality of switches may be turned on or turned off according to a distribution control signal of the driving processor 2116.

The current sensing circuit 2115 may include a current sensor that measures the current output by the inverter circuit 1. The current sensor may transmit an electrical signal corresponding to the value of the measured current to the driving processor 2116. According to an embodiment of the disclosure, the current sensor may be a plurality of current sensors.

The driving processor 2116 may determine a switching frequency (turn-on/turn-off frequency) of the switching circuit included in the inverter circuit 1, based on the output intensity (power level) of the heating device 2000. The driving processor 2116 may generate a driving control signal for turning on/off the switching circuit according to the determined switching frequency. According to an embodiment of the disclosure, an operation of the driving processor 2116 may be replaced by the processor 42.

The heating coil 2120 may create a magnetic field for heating a cooking appliance 10. For example, when a driving current is supplied to the heating coil 2120, a magnetic field may be induced around the heating coil 2120. When a current whose magnitude and direction change with time, that is, an AC current, is supplied to the heating coil 2120, a magnetic field whose magnitude and direction change with time may be induced around the heating coil 2120. The magnetic field around the heating coil 2120 may pass through a top plate made of tempered glass, and may reach the cooking appliance 10 placed on the top plate. Due to the magnetic field whose magnitude and direction change with time, an eddy current rotating about the magnetic field may be created in the cooking appliance 10, and electrical resistance heat may be generated in the cooking appliance 10 due to the eddy current. The electrical resistance heat is heat generated in a resistor when a current flows in the resistor and is also called Joule heat. The cooking appliance 10 may be heated by the electric resistance heat, and contents inside the cooking appliance 10 may be heated.

The processor 42 controls all operations of the heating device 2000. The processor 42 may control the wireless power transmitter 2100, the communication interface 2300, the sensor unit 2400, the user interface 2500, and the memory 2600 by executing programs stored in the memory 2700.

According to an embodiment of the disclosure, the heating device 2000 may include an artificial intelligence (AI) processor. The AI processor may be manufactured in the form of an exclusive hardware chip for AI or may be manufactured as a part of an existing general-purpose processor (for example, a central processing unit (CPU) or an application processor) or a graphic-exclusive processor (for example, a graphics processing unit (GPU)) and may be mounted on the heating device 2000.

According to an embodiment of the disclosure, based on food temperature data obtained by the sensor unit 2400, the processor 42 may perform an automatic cooking operation by controlling a power level, or may control the user interface 2500 to output information for guiding cooking to a user. In addition, based on internal temperature data obtained by the sensor unit 2400, the processor 42 may output notification information about the sensor unit 2400 when an internal temperature of the sensor unit 2400 is equal to or higher than a reference temperature, or may control the power level. Based on the information about the remaining amount of the battery received from the sensor unit 2400, the processor 42 may control the user interface 2500 to output information about the remaining amount of the battery when the remaining amount of the battery is less than a threshold value.

The communication interface 2300 may include at least one component that enables communication between the heating device 2000 and a server device. For example, the communication interface 2300 may include a short-range wireless communication interface 2310 and a mobile communication interface 2320. Examples of the short-range wireless communication interface may include, but are not limited to, a Bluetooth communication interface, a Bluetooth Low Energy (BLE) communication interface, a near field communication (NFC) interface, a wireless local area network (WLAN) (e.g., Wi-Fi) communication interface, a ZigBee communication interface, an infrared Data Association (IrDA) communication interface, a Wi-Fi direct (WFD) communication interface, an ultra wideband (UWB) communication interface, and an Ant+ communication interface. The mobile communication interface 2320 may exchange a wireless signal with at least one selected from a base station, an external terminal, and a server on a mobile communication network. Here, examples of the wireless signal may include a voice call signal, a video call signal, and various types of data according to text/multimedia message exchange. The mobile communication interface 2320 may include, but is not limited to, a 3G module, a 4G module, an LTE module, a 5G module, a 6G module, an NB-IoT module, and an LTE-M module.

The sensor unit 2400 may include a vessel detection sensor 2410 and a temperature sensor 2420, but embodiments of the disclosure are not limited thereto.

The vessel detection sensor 2410 may be a sensor that detects that the cooking appliance 10 is placed on the top plate. For example, the vessel detection sensor 2410 may be implemented as a current sensor, but embodiments of the disclosure are not limited thereto. The vessel detection sensor 2410 may be implemented as at least one of a proximity sensor, a touch sensor, a weight sensor, a temperature sensor, an illuminance sensor, and a magnetic sensor.

The temperature sensor 2420 may detect the temperature of the cooking appliance 10 placed on the top plate or the temperature of the top plate. The cooking appliance 10 may be inductively heated by the heating coil 2120, and may be overheated according to materials. Accordingly, the heating device 2000 may detect the temperature of the cooking appliance 10 placed on the top plate or the temperature of the top plate, and may block an operation of the heating coil 2120 when the cooking appliance 10 is overheated. The temperature sensor 2420 may be installed near the heating coil 2120. For example, the temperature sensor 2420 may be located at the center of the heating coil 2120.

According to an embodiment of the disclosure, the temperature sensor 2420 may include a thermistor whose electrical resistance value changes according to temperature. For example, a temperature sensor may use, but is not limited to, a negative temperature coefficient (NTC) temperature sensor. The temperature sensor may be a positive temperature coefficient (PTC) temperature sensor.

The user interface 2500 may include an output interface and an input interface 2530. The output interface is provided to output an audio signal or a video signal, and may include a display 2510, an audio output interface 2520, etc.

When the display 2510 forms a layer structure together with a touch pad to construct a touch screen, the display 2510 may be used as the input interface 2530 as well as the output interface. The display 2510 may include at least one selected from a liquid crystal display (LCD), a thin film transistor-liquid crystal display (TFT-LCD), a light-emitting diode (LED), an organic light-emitting diode (OLED), a flexible display, a 3D display, and an electrophoretic display. According to embodiments of the heating device 2000, the heating device 2000 may include two or more displays 2510.

The audio output interface 2520 may output audio data that is received from the communication interface 2300 or stored in the memory 2600. The audio output interface 2520 may output audio signals related to functions performed by the heating device 2000. The audio output interface 2520 may include, for example, a speaker and a buzzer.

According to an embodiment of the disclosure, the display 2510 may output, for example, information about a current power level, information about a current cooking mode, information about a cooking area currently in use, and information about a current temperature of the contents in the cooking appliance 10, and information for guiding cooking.

The input interface 2530 is for receiving an input from a user. The input interface 2530 may include, but is not limited to, at least one of a key pad, a dome switch, a touch pad (e.g., a capacitive overlay type, a resistive overlay type, an infrared beam type, an integral strain gauge type, a surface acoustic wave type, a piezoelectric type, or the like), a jog wheel, or a jog switch.

The input interface 2530 may include a voice recognition module. For example, the heating device 2000 may receive a speech signal, which is an analog signal, through a microphone, and may convert the speech signal into computer-readable text by using an automatic speech recognition (ASR) model. The heating device 2000 may also obtain a user's utterance intention by interpreting the converted text using a Natural Language Understanding (NLU) model. The ASR model or the NLU model may be an AI model. The AI model may be processed by an AI-only processor designed with a hardware structure specialized for processing the AI model. The AI model may be created through learning. Here, being created through learning means that a basic AI model is trained using a plurality of learning data by a learning algorithm, so that a predefined operation rule or AI model set to perform desired characteristics (or a desired purpose) is created. The AI model may be composed of a plurality of neural network layers. Each of the plurality of neural network layers has a plurality of weight values, and performs a neural network operation through an operation between an operation result of a previous layer and the plurality of weight values.

Linguistic understanding is a technology that recognizes and applies/processes human language/character, and thus includes natural language processing, machine translation, a dialog system, question answering, and speech recognition/speech recognition/synthesis, etc.

The memory 2600 may store a program for processing and control of the processor 42, and may store input/output data (for example, a cooking recipe, reference temperature data, and remaining capacity information of a battery 1060). The memory 2600 may store an AI model.

The memory 2600 may include at least one type of storage medium selected from among a flash memory type, a hard disk type, a multimedia card micro type, a card type memory (for example, a secure digital (SD) or extreme digital (XD) memory), a random access memory (RAM), a static random access memory (SRAM), a read-only memory (ROM), an electrically erasable programmable ROM (EEPROM), a programmable ROM (PROM), magnetic memory, a magnetic disk, and an optical disk. The heating device 2000 may operate a web storage or a cloud server which performs a storage function on the Internet.

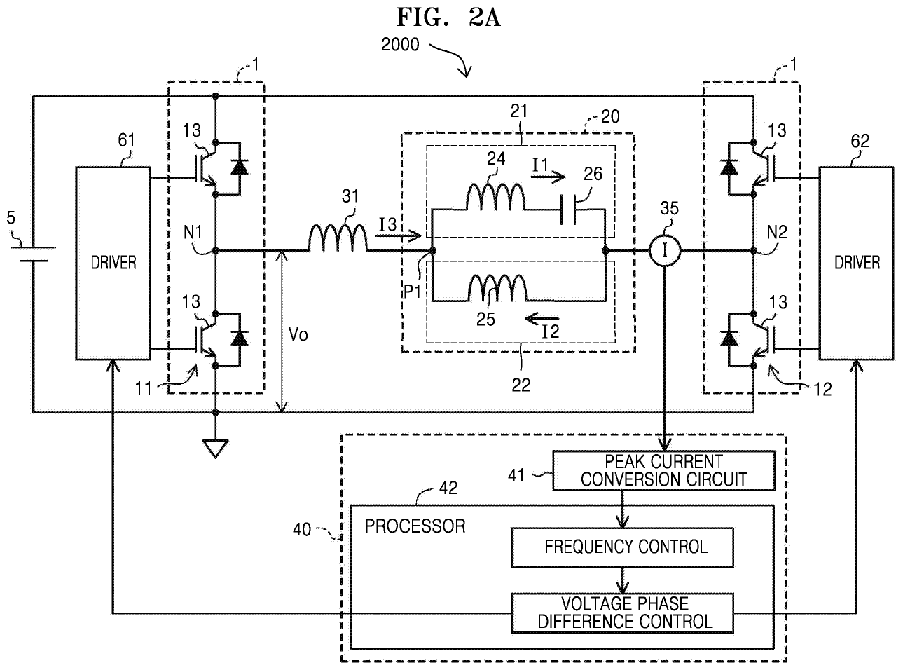

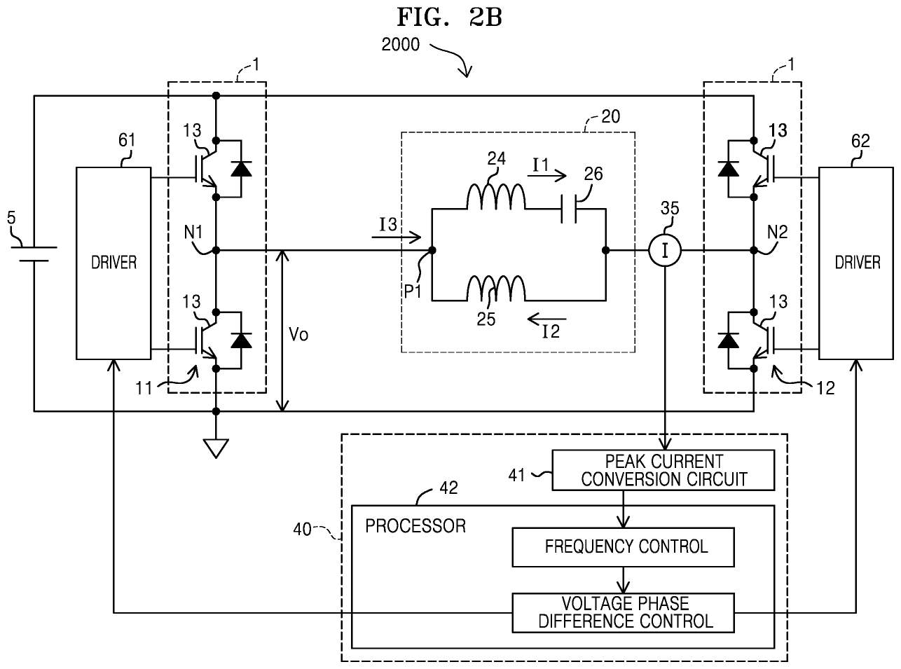

FIGS. 2A and 2B area diagrams for explaining cooking systems according to an embodiment of the disclosure.

As shown in FIG. 2A, the heating device 2000 includes a parallel resonance circuit 20 composed of a heating coil C, inductors 24 and 25 including the heating coil C, and a resonance capacitor 26, an inverter circuit 1 for supplying power to the parallel resonance circuit 20, a first current sensor 35 for detecting an output current of the inverter circuit 1 (hereinafter, referred to as an inverter current I3), and a controller 40. The controller 40 may include the processor 42.

Compared with FIG. 1, in the heating device 2000 according to FIG. 2A, a rectifier for rectifying an initial AC source is omitted, and a DC capacitor for establishing a DC source by using a rectifier is replaced with a DC source 5 for convenience of description. However, this is only an embodiment. As described above with reference to FIG. 1, the heating device 2000 according to the disclosure may include all of an AC source, a rectifier for rectifying the AC source, and a DC capacitor.

A circuit configuration of the inverter circuit 1 is not particularly limited, and may apply conventionally-known configurations. The present embodiment represents an example of the inverter circuit 1 having a full bridge configuration in which arms 11 and 12 are connected in parallel. An inverter circuit according to another embodiment may be configured in the form of a half bridge having one arm.

Each of the arms 11 and 12 of the inverter circuit 1 has two switching devices 13 connected in series. The two switching devices 13 of the arm 11 are connected to each other by first wiring N1, and the two switching devices 13 of the arm 12 are connected to each other by second wiring N2. Each of the switching devices 13 is a parallel circuit of a transistor and a diode connected in parallel with the transistor and in the opposite direction to the transistor. The switching devices 13 of the arm 11 perform switching operations by receiving a driving signal from a driver 61 operating under the control of the processor 42 described later. Likewise, the switching devices 13 of the arm 12 perform switching operations by receiving a driving signal from a driver 62 operating under the control of the processor 42. By the switching operations of the arms 11 and 12, DC power is converted to AC power and output. The switching device of the arm 11 may be any type of switching device such as a transistor, a field effect transistor (FET), or an insulated gate bipolar mode transistor (IGBT).

A voltage filter coil 31, the parallel resonance circuit 20, and a first current sensor 35 are connected in series between the first wiring N1 and the second wiring N2. As the first current sensor 35, any type of current sensor capable of sensing a current in real time may be used. According to an embodiment of the disclosure, the first current sensor 35 may use a current transformer (CT).

The voltage filter coil 31 is inserted between an output of the inverter circuit 1 and the parallel resonance circuit 20, and a square wave voltage generated by the inverter circuit 1 is filtered so that an inverter current I3 approaches a sine wave, and thus acts to become the sine wave. Thus, even when an effective value of an output voltage of the inverter circuit 1 (hereinafter, referred to as an inverter voltage Vo) is small with respect to an input voltage, which is the DC source 5, a resonance frequency based on a peak current may be controlled. Because the DC source 5, which is an input voltage, is switched and generated, the inverter voltage Vo has basically a square wave shape. Instead of the voltage filter coil 31, another filter circuit may be used that removes harmonic components of the inverter voltage Vo and filters the waveform so that the waveform of the voltage Vo becomes a sine wave shape. The control of the resonance frequency based on the peak current will be described in more detail later.

The parallel resonance circuit 20 has a configuration in which an inductor 25 is connected in parallel to a first circuit 21 in which an inductor 24 and a resonance capacitor 26 are connected in series.

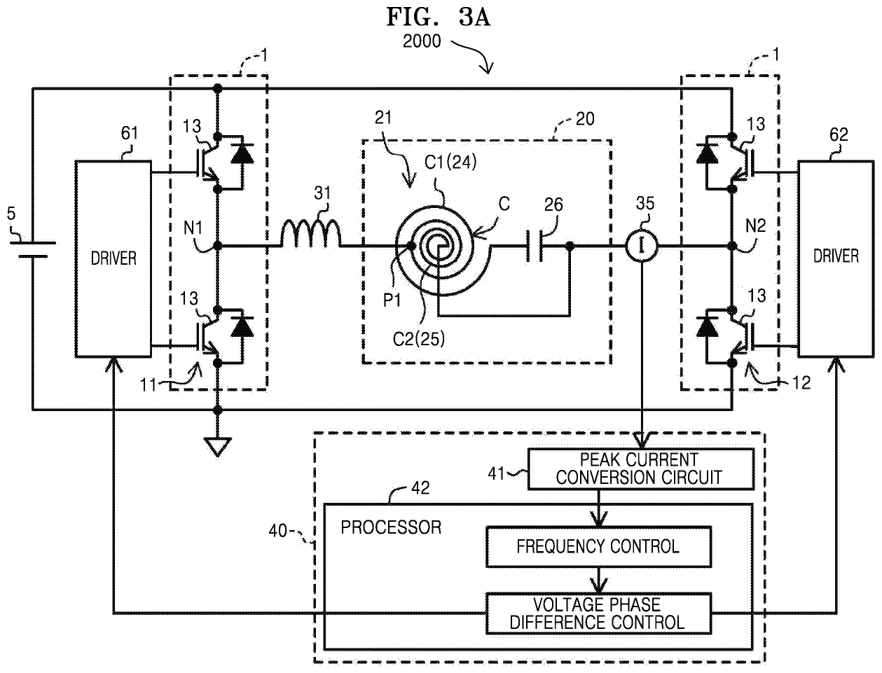

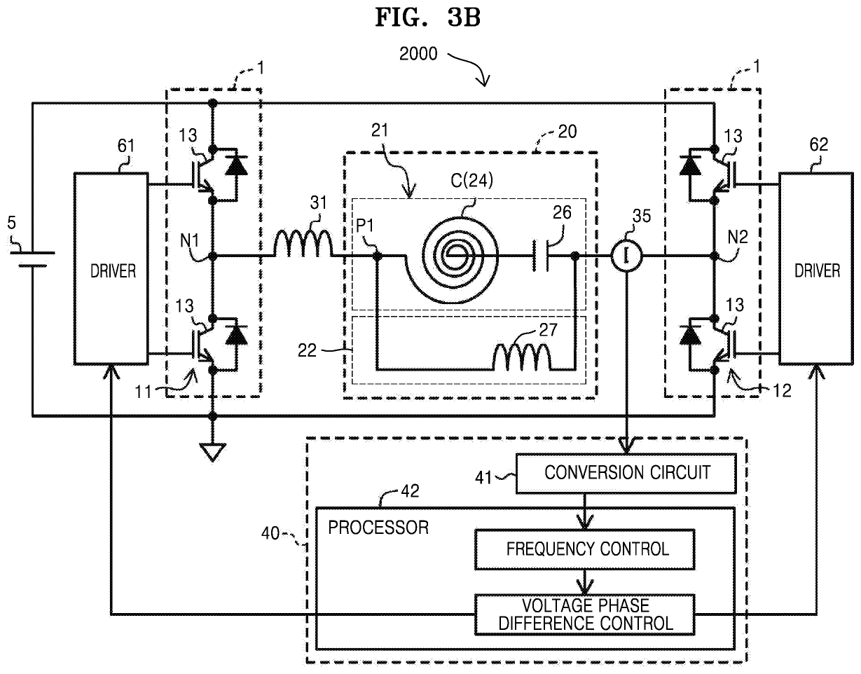

A more detailed description of the parallel resonance circuit 20 will now be given with reference to FIGS. 3A and 3B.

FIGS. 3A and 3B are detailed diagrams of a heating device according to an embodiment of the disclosure.

FIGS. 3A and 3B show detailed configuration examples of the parallel resonance circuit 20 according to FIG. 2A. In FIGS. 3A and 3B, a heating coil C is spirally wound in a predetermined direction.

In FIG. 3A, the heating coil C has one end connected to the second wiring N2 through the first current sensor 35 and the other end connected to the second wiring N2 through the resonance capacitor 26 and the first current sensor 35. A midpoint P1 located in the middle of the heating coil C is connected to the first wiring N1 via the voltage filter coil 31. In other words, the heating coil C is divided into a first heating coil C1 and a second heating coil C2, based on the midpoint P1. The first heating coil C1 constitutes an inductor 24, and the second heating coil C2 constitutes another inductor 25.

In FIG. 3B, the parallel resonance circuit 20 has a configuration in which a first circuit 21 in which the heating coil C and the resonance capacitor 26 are connected to each other in series and are connected in parallel to a second circuit 22 composed of the inductor 25. In the case of the heating device 2000 of FIG. 3B, the heating coil C includes the inductor 24.

Referring back to FIG. 2A, the controller 40 includes the peak current conversion circuit 41 and the processor 42, which controls the driving frequency of the inverter circuit 1, based on the peak current of the output current detected by the first current sensor 35. Although not shown in FIG. 2A, the controller 40 may include a memory and a user interface as needed.

The peak current conversion circuit 41 is a circuit that converts the output current detected by the first current sensor 35 into a peak current, in other words, a circuit that detects the peak current value of the inverter current I3. The peak current conversion circuit 41 outputs a peak current value (hereinafter, simply referred to as a peak current value) to the processor 42 for each cycle of the driving frequency of the inverter circuit 1. When the first current sensor 35 is not a sensor for detecting an effective value but a CT for detecting an AC in real time, the controller 40 does not selectively include the peak current conversion circuit 41.

Based on the peak current value received from the peak current conversion circuit 41, the processor 42 controls the driving frequency of the inverter circuit 1 so that the peak current value is a minimum value or is within a certain threshold value. According to an embodiment, when the effective value of the inverter voltage Vo is fixed, based on the peak current value received from the peak current conversion circuit 41, the processor 42 may control the driving frequency of the inverter circuit 1 so that the peak current value is a minimum value or is within a certain threshold value. As shown in FIG. 2A, the processor 42 may output a voltage phase difference control command to the inverter circuit 1 via the drivers 61 and 62 in order to control the driving frequency of the inverter circuit 1.

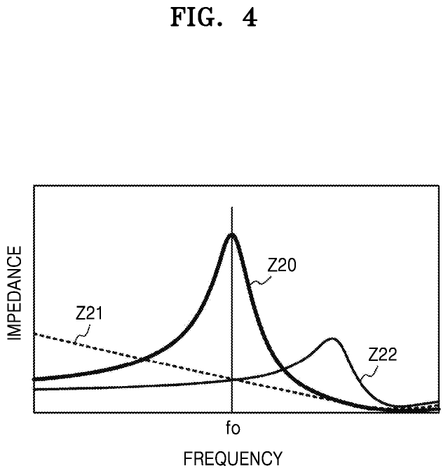

FIG. 4 is a graph showing an example of frequency-impedance characteristics of the parallel resonance circuit 20, according to an embodiment of the disclosure.

In FIG. 4, the thick solid line represents an impedance Z20 of the parallel resonance circuit 20, the dotted line represents an impedance Z21 of the first circuit 21, and the thin solid line represents an impedance Z22 of the second circuit 22.

A frequency at which the impedance Z20 of the parallel resonance circuit 20 represents a maximum value is a resonance frequency fo. When the parallel resonance circuit 20 resonates at the resonant frequency fo, the impedance Z21 of the first circuit 21 and the impedance Z22 of the second circuit 22 are expressed by Equation 1 below. The impedance Z20 of the parallel resonance circuit 20 may be expressed by Equation 2 below.

$$\begin{matrix}Z 21 = Z 22 \approx \frac{{L}_{s} + M}{\sqrt{( {L}_{m}} + {L}_{s} + 2 M ) \cdot {C}_{m}} = 2 π {f}_{o} ( {L}_{s} + M ) & [ Equation 1 ] \\ Z 20 \approx \frac{Z {21}^{2}}{{R}_{m +} {R}_{s} + 2 {R}_{t}} & [ Equation 2 ]\end{matrix}$$

In Equation 1, Lm indicates the inductance of the first circuit 21 (here, the inductor 24), Ls indicates the inductance of the second circuit 22 (here, the inductor 25), M indicates a mutual inductance between the first circuit 21 and the second circuit 22, and Cm indicates a capacitance value of the first circuit 21 (here, the resonance capacitor 26). Equation 2 is an expression in a state where a pot is placed on the heating coil C, wherein Rm is a resistance component of the first circuit 21 including an influence of the pot, Rs is a resistance component of the second circuit 22 including the influence of the pot, and Rt is a resistance component corresponding to a mutual inductor.

In Equation 1, the impedance Z21 is determined by the number of windings of the heating coil C and the size of a cooking appliance (e.g., a pot), which is an object to be heated, and hardly depends on the material of the cooking appliance. The value of the impedance Z21 is designed to be, for example, about 3 to 10 [Ω].

In the case of an aluminum pot, (Rm+Rs+2Rt) is about 1 [Ω], and, from Equations 1 and 2, the impedance Z20 is about 10 to 100 [Ω]. In other words, in the case of an aluminum pot, a relationship between the impedance Z20 and the impedances Z21 and Z22 is (Z20>Z21, Z22).

In the case of an SUS pot, (Rm+Rs+2Rt) is about 20 [Ω], and, from Equations 1 and 2, the impedance Z20 is about 0.05 to about 5 [Ω]. In other words, in the case of an SUS pot, a relationship between the impedance Z20 and the impedances Z21 and Z22 is (Z20<Z21, Z22).

To summarize the impedance Z20 of the parallel resonance circuit 20, in the case of a non-magnetic pot such as an aluminum pot, at a parallel resonance frequency, the impedance Z20 of the parallel resonance circuit 20 is greater than the impedance Z21 of the first circuit 21 and is also greater than the impedance Z22 of the second circuit 22.

Control of the driving frequency of the inverter circuit 1 will now be described in detail. The control of the driving frequency of the inverter circuit 1 will now be described separately in a case where the voltage filter coil 31 is provided in the circuit, as shown in FIG. 2A and a case where the voltage filter coil 31 is not provided in the circuit, as shown in FIG. 2B.

According to an embodiment, the controller 40 performs control differently in a first embodiment where the voltage filter coil 31 is included or the voltage filter coil 31 is not included but the effective value of the inverter voltage Vo is relatively large and a second embodiment where the voltage filter coil 31 is not included and/or the effective value of the inverter voltage Vo is relatively small.

A boundary between the relative magnitudes of the effective value of the inverter voltage Vo is arbitrarily set according to configurations of a circuit and the like. For example, the controller 40 determines that the effective value of the inverter voltage Vo is relatively large when the effective value of the inverter voltage Vo is 60% or more of the input voltage Vi of the inverter circuit 1 (hereinafter, simply referred to as the effective value being large), and determines that the effective value of the inverter voltage Vo is relatively small when the effective value of the inverter voltage Vo is less than 60% of the input voltage Vi of the inverter circuit 1 (hereinafter, simply referred to as the effective value being small).

Control of the driving frequency of the inverter circuit 1 by the controller 40 when the voltage filter coil 31 is included in the first circuit 21 and/or when the effective value of the inverter voltage Vo is large will be first described.

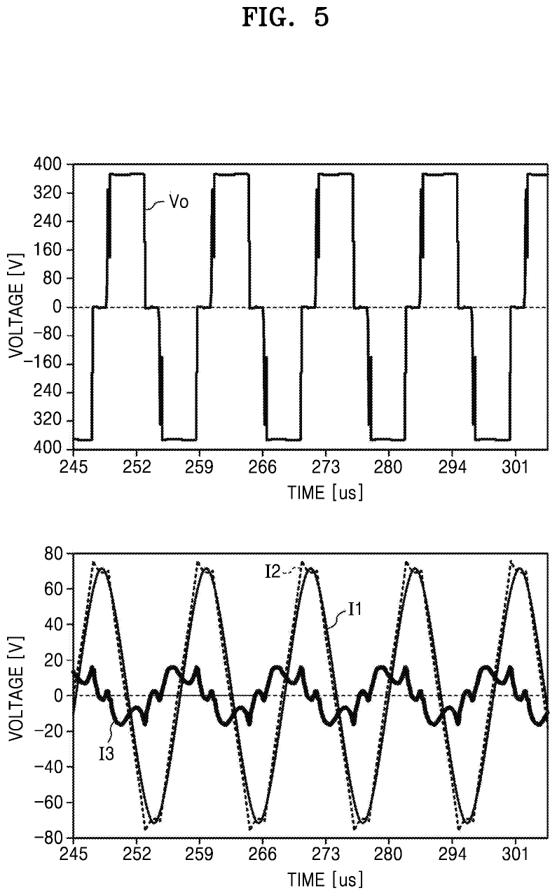

FIG. 5 illustrates graphs showing the waveform of an inverter voltage and the waveform of a current flowing in a parallel resonance circuit, according to an embodiment of the disclosure.

An upper portion of FIG. 5 shows a waveform of the inverter voltage Vo over time, and as illustrated the inverter voltage Vo in the inverter circuit 1 appears in the form of a square wave due according to a switching operation. A lower portion of FIG. 5 illustrates waveforms showing changes, over time, in a branch current I1 flowing in the first circuit 21 of the parallel resonance circuit 20, branch currents I1 and I2 flowing in the second circuit 22 of the parallel resonance circuit 20, and the inverter current I3 of the parallel resonance circuit 20. As shown in FIG. 5, when the voltage filter coil 31 is included in the first circuit 21 and/or when the effective value of the inverter voltage Vo is large, the inverter current I3 becomes closer to a sine wave.

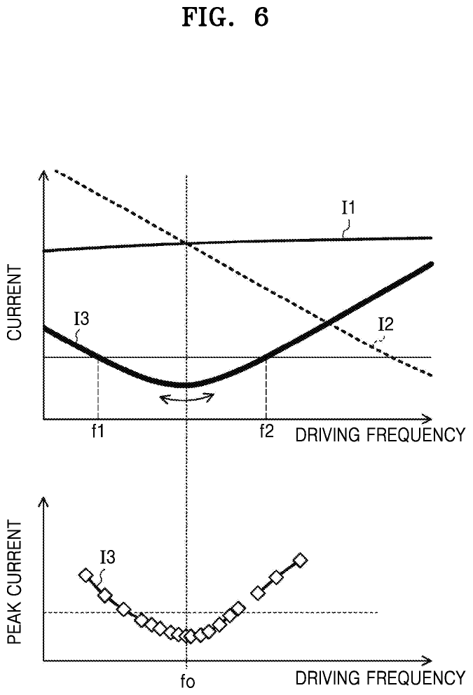

FIG. 6 are graphs illustrating AC interpretation of the branch currents I1 and I2 and the inverter current I3 of the parallel resonance circuit 20 around the resonance frequency fo, according to an embodiment of the disclosure.

As shown in an upper waveform of FIG. 6, when the branch current I1 of the first circuit 21 and the branch current I2 of the second circuit 22 are substantially the same as each other, the parallel resonance circuit 20 resonates and thus heating is performed most efficiently. In FIG. 6, the upper waveform shows a result of AC interpretation of the branch currents I1 and I2 and the inverter current I3 for a driving frequency near the resonance frequency fo, and the lower waveform shows a change in a measured value of the peak current value Ip for the driving frequency.

As illustrated in FIG. 6, a frequency when the inverter current I3 is at a minimum value in the above AC interpretation and a frequency when the inverter current I3 is at a minimum value in an actual operation are almost the same as the resonant frequency fo. For example, when the resonance frequency fo of the parallel resonance circuit 20 by AC interpretation is 75.95 [kHz], the driving frequency into which the minimum value (actually measured value) of the inverter current I3, which is an output current, is converted is 76.0 [kHz], and the heating device 2000 is substantially able to operate at a resonance frequency by minimizing the peak current value Ip.

Therefore, when the effective value of the inverter voltage Vo is large, the processor 42 may control the driving frequency of the inverter circuit 1 such that the peak current value Ip based on a result of the detection by the first current sensor 35 is minimized. This allows the heating device 2000 to operate at a resonance frequency.

A detailed method of controlling the driving frequency of the inverter circuit 1 by the processor 42 is not particularly limited. According to an embodiment, the processor 42 may control the driving frequency of the inverter circuit 1 in a direction in which a slope AI of the output current for a change Δf in the driving frequency decreases, while constantly varying the driving frequency of the inverter circuit 1 finely (e.g., by less than 1 [kHz]). In other words, the processor 42 may control the driving frequency of the inverter circuit 1 such that ΔI/Δf becomes closer to zero.

According to another embodiment, the processor 42 may set a threshold value Ith1 to the inverter current I3 according to an output level of the heating device 2000, and control the driving frequency of the inverter circuit 1 to be the threshold value Ith1 or less. For example, when the output power of the heating device 2000 is 2500 [W], it is assumed that, when a standard-sized aluminum pot is installed, the resistance value of a heating coil at the driving frequency is designed to be 1 [Ω]. At this time, a current flowing in the heating coil becomes 50 [A]. Because each impedance value when an aluminum pot is installed has a correlation with the size of the aluminum pot, the values of Equations 1 and 2 are obtained in the case of a standard-sized pot. For example, Z21=Z22=6[Ω], and Z20=36[Ω]. In this case, the inverter current I3 which is theoretically obtained becomes [output current XZ21/Z20], namely, 8.3[A].

Then, the inverter current I3 which is theoretically obtained has a peak current of 11.7[A]. Therefore, when 14 [A], which is about 20% larger than the peak current, is set as a threshold value of the control, the driving frequency of the inverter circuit 1 may be controlled within the range of the resonance frequency fo±350 [Hz]. Of course, this is an application according to an embodiment, and the threshold value may be set to be larger or smaller than 20%, according to design needs.

According to an embodiment of the disclosure, control of the driving frequency of the inverter circuit 1 of the heating device 2000 when the voltage filter coil 31 is not included in the heating device 2000 and/or the effective value of the inverter voltage Vo is relatively small will be described.

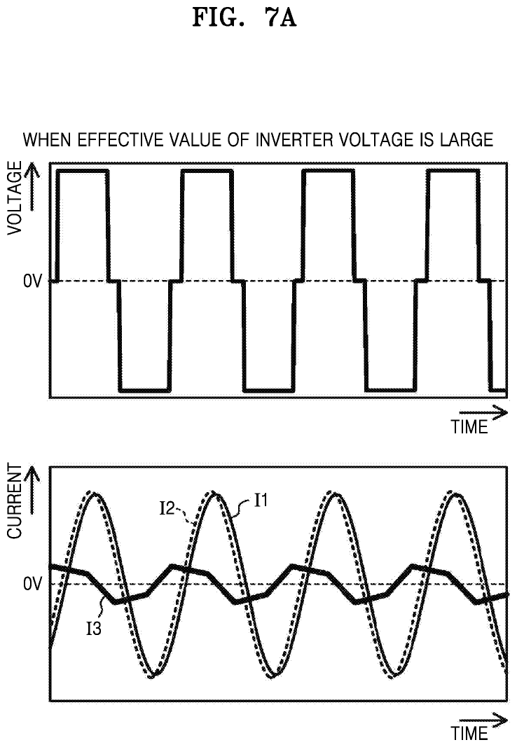

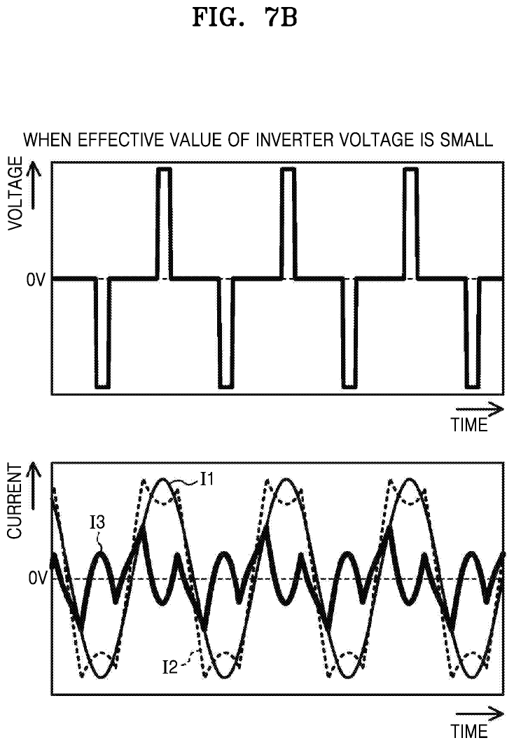

FIG. 7A is a diagram illustrating waveforms of the inverter voltage Vo and the currents I1, I2, and I3 of a parallel resonance circuit when the effective value of the inverter voltage Vo is large, according to an embodiment of the disclosure.

Referring to FIG. 7A, when the effective value of the inverter voltage Vo is relatively large, the inverter current I3 is close to a sine wave shape. A frequency when the inverter current I3 is at a minimum value in the above AC interpretation and a frequency when the output current I3 is at a minimum value in an actual operation are almost the same as the resonant frequency fo.

FIG. 7B is a diagram illustrating waveforms of the inverter voltage Vo and the currents I1, I2, and I3 of a parallel resonance circuit when the effective value of the inverter voltage Vo is small, according to an embodiment of the disclosure.

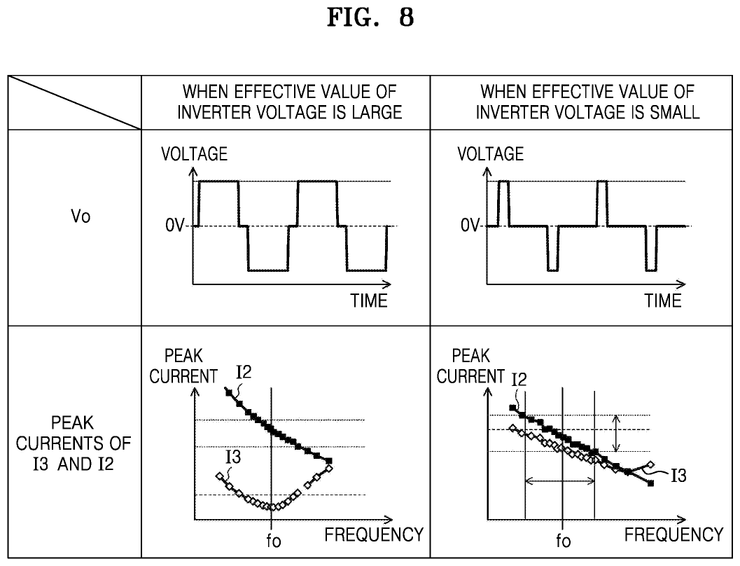

FIG. 8 is a table illustrating correlations with a peak current flowing in a parallel resonance circuit when the effective value of the inverter voltage Vo, which is an output voltage of an inverter circuit, is large and when the effective value of the inverter voltage Vo, which is an output voltage of an inverter circuit, is small, according to an embodiment of the disclosure.

FIG. 8 illustrates a correlation between peak currents I2 and I3 flowing in the parallel resonance circuit for each frequency when the effective value of the inverter voltage Vo is greater than a predetermined value. The peak value of the output current I3 shows a minimum value near the resonant frequency fo.

Referring to FIG. 7B together with FIG. 8, it may be seen that, when the effective value of the inverter voltage Vo is less than the predetermined value, the output current I3, which is the inverter current, is not close to a sine wave shape. As can be seen through FIG. 8, when the effective value of the inverter voltage Vo is less than the predetermined value, the frequency at which the output current I3 is at a minimum value in an actual operation is not consistent with the resonance frequency fo. Therefore, when the effective value of the inverter voltage Vo of the heating device 2000 is less than the predetermined value, it is necessary to employ a method different from that in the case where the effective value Vo of the inverter voltage is greater than the predetermined value.

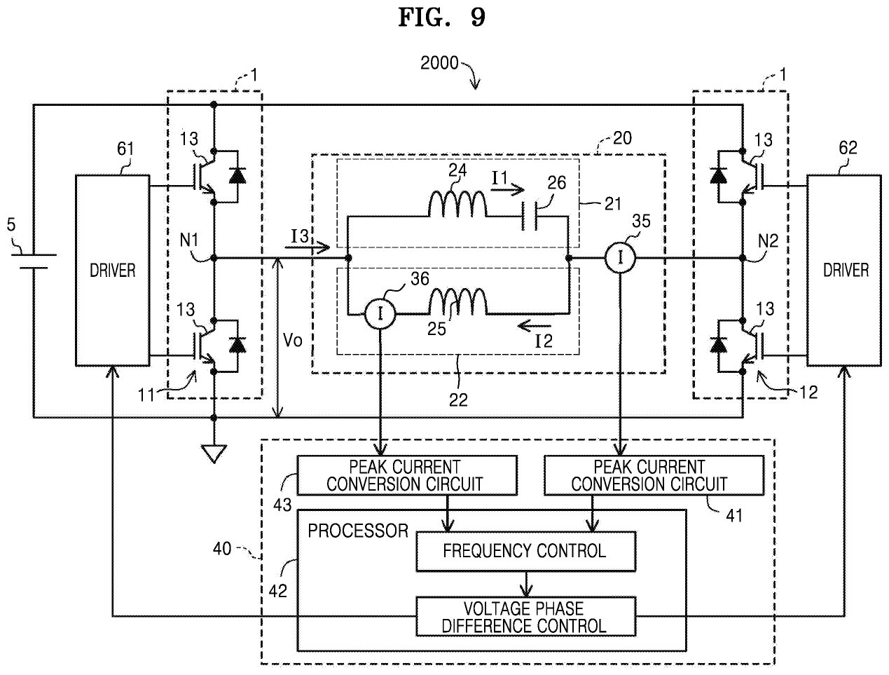

A structure of the parallel resonance circuit 20 employed when the heating device 2000 has a small effective value of the inverter voltage Vo will be described with reference to FIG. 9. The embodiment according to FIG. 8 is applicable even when the heating device 2000 does not include the voltage filter coil 31.

FIG. 9 is a circuit diagram of a heating device 2000 including a second current sensor 36 in a parallel resonance circuit 20, according to an embodiment of the disclosure.

Referring to FIG. 9, the heating device 2000 further includes, in addition to the first current sensor 35, a second current sensor 36 for detecting a current flowing through the parallel resonance circuit 20. According to an embodiment, the second current sensor 36 may be installed in the first circuit 21 or may be installed in the second circuit 22.

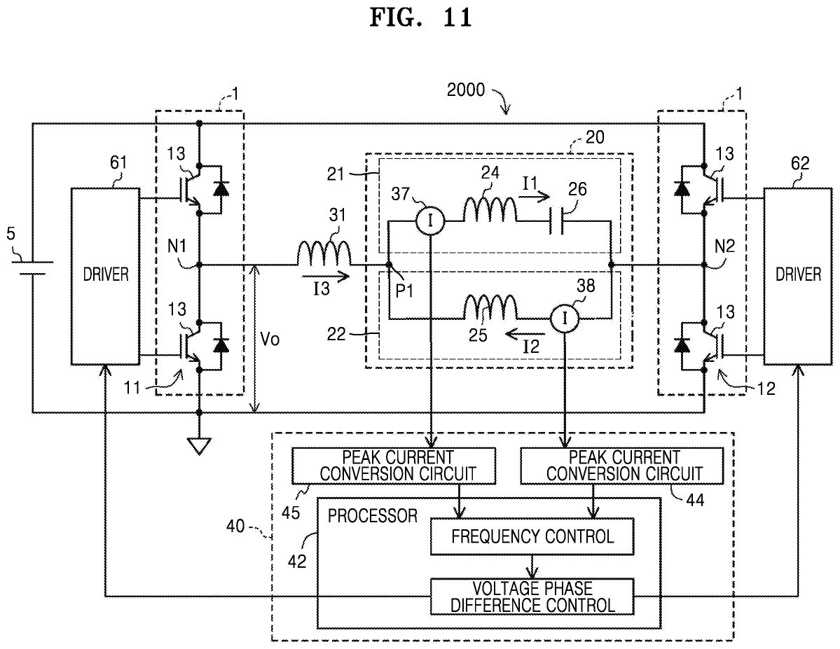

According to another embodiment, a first current sensor 37 is installed in the first circuit 21 and a second current sensor 38 is installed in the second circuit 22. FIG. 11 is a circuit diagram of a heating device 2000 in which the first current sensor 37 is installed in the first circuit 21 and the second current sensor 38 is installed in the second circuit 22, according to an embodiment of the disclosure.

Each method will now be described with reference to the drawings.

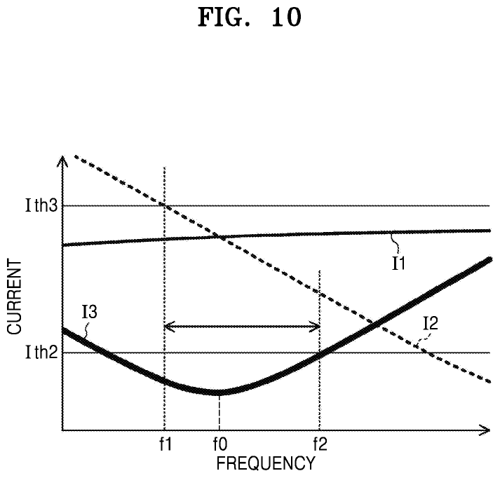

First, the heating device 2000 of FIG. 9 will be referred to. In FIG. 9, the same reference numerals as those in FIG. 2A are assigned to components common to those in FIG. 2A, and differences will be mainly described here. For convenience of explanation, the differences will be described with reference to FIG. 10 together with FIG. 9.

FIG. 10 is a graph showing changes in the branch currents I1 and I2 and the inverter current I3 of the parallel resonance circuit 20 with respect to a driving frequency in the horizontal axis, in the circuit diagram of FIG. 9, according to an embodiment of the disclosure.

The heating device 2000 of FIG. 9 according to an embodiment of the disclosure further includes, in addition to the first current sensor 35, the second current sensor 36 for detecting a current flowing through the parallel resonance circuit 20. FIG. 9 illustrates an embodiment in which the second current sensor 36 is installed in the second circuit 22.

The controller 40 includes a peak current conversion circuit 43 that converts an output current detected by the second current sensor 36 into a peak current. When the second current sensor 36 is a CT that reflects a current value of a current without changes, the controller 40 may selectively not include the peak current conversion circuit 43. The processor 42 may control the driving frequency of the inverter circuit 1, based on the peak current value of the inverter current I3 received from the peak current conversion circuit 41 and the peak current value of the branch current I2 flowing in the second circuit 22 received from the peak current conversion circuit 43.

According to an embodiment, when the inverter current I3 exceeds a predetermined threshold value Ith2, the processor 42 controls the driving frequency of the inverter circuit 1 to be lowered. Referring to FIG. 10, because the driving frequency at the threshold value Ith2 is f2 (where f2>fo), the processor 42 controls the heating device 2000 to lower the driving frequency to less than f2.

When the branch current I2 flowing in the second circuit 22 exceeds a predetermined threshold value Ith3 (where Ith3>Ith2), the processor 42 controls the driving frequency of the inverter circuit 1 to be increased. Referring to FIG. 9, because the driving frequency at the threshold value Ith3 is f1 (where f12<fo<f2), the processor 42 controls the heating device 2000 to increase the driving frequency to more than f1.

Accordingly, the processor 42 may appropriately adjust the driving frequency of the inverter circuit 1 between f1 and f2. In other words, the processor 42 may control the driving frequency of the inverter circuit 1 to be close to the resonance frequency fo of the parallel resonance circuit 20. Because the processor 42 is able to adjust the driving frequency even while the cooking appliance is being heated by the heating device 2000, even when the pot is moved and a resonance point is out of range, the processor 42 may control the driving frequency so that the heating device 2000 automatically operates at the resonance point.

Because the driving frequencies f1 and f2 may be set as arbitrary values by the threshold values Ith2 and Ith3, respectively, an interval between the driving frequencies f1 and f2 may be adjusted. In other words, when the magnitudes of the threshold values Ith2 and Ith3 are adjusted, the interval between the frequency interval between the driving frequency f1 and the driving frequency f2 is also automatically adjusted.

FIG. 11 is a circuit diagram of a heating device 2000 in which the first current sensor 37 is installed in the first circuit 21 and the second current sensor 38 is installed in the second circuit 22, according to an embodiment of the disclosure.

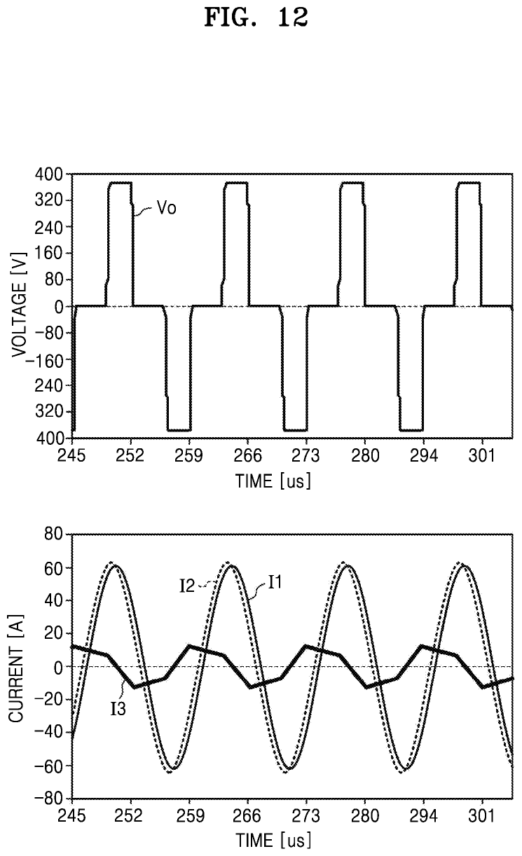

In FIG. 11, the same reference numerals as those in FIG. 2A are assigned to components common to those in FIG. 2A, and differences will be mainly described here. For convenience of explanation, the differences will be described with reference to FIG. 12 together with FIG. 11.

FIG. 12 is a graph showing changes in the inverter voltage Vo and the branch currents I1 and I2 and the inverter current I3 of the parallel resonance circuit 20 with respect to time in the horizontal axis, in the circuit diagram of FIG. 11, according to an embodiment of the disclosure.

As described above, the heating device 2000 of FIG. 11 according to an embodiment of the disclosure includes the first current sensor 37 for detecting the branch current I1 flowing in the first circuit 21, and the second current sensor 38 for detecting the branch current I2 flowing in the second circuit 22.

The controller 40 includes a peak current conversion circuit 44 that converts the branch current I1 detected by the first current sensor 37 into a peak current, and a peak current conversion circuit 45 that converts the branch current I2 detected by the second current sensor 38 into a peak current. According to an embodiment, when the first and second current sensors 37 and 38 are CTs that reflect a current value of a current without changes, the controller 40 may selectively not include the peak current conversion circuits 44 and 45.

The processor 42 controls the driving frequency of the inverter circuit 1, based on the peak current value of the branch current I1 received from the peak current conversion circuit 44 and the peak current value of the branch current I2 received from the peak current conversion circuit 45. Alternatively, when the first and second current sensors 37 and 38 are CTs that reflect a current value of a current without changes, the processor 42 controls the driving frequency of the inverter circuit 1, based on the peak current values detected by the first current sensor 37 and the second current sensor 38.

According to an embodiment, when the parallel resonance circuit 20 is resonating, the inverter current I3 becomes a minimum value, and the waveform of the branch current I1 flowing in the first circuit 21 and the waveform of the branch currents I2 flowing in the second circuit 22 become ideally the same as each other. The processor 42 controls the driving frequency of the inverter circuit 1 so that the peak current of the branch current I1 is consistent with the peak current of the branch current I2 or the peak current of the branch current I1 and the peak current of the branch current I2 are within a predetermined range.

By doing this, the processor 42 may control the driving frequency of the inverter circuit 1 to be close to the resonance frequency fo of the parallel resonance circuit 20. Because the controller 40 is able to adjust the driving frequency even while the heating device 2000 is heating the cooking appliance, even when a pot, which is the cooking appliance, is moved and a resonance point is out of range, the controller 40 may control the heating device 2000 to automatically operate at the resonance point.

As described above, preferred embodiments have been described as examples of the technology of the disclosure. However, the technology of the disclosure is not limited thereto, and may be applied to embodiments in which changes, substitutions, additions, omissions, and the like have been appropriately performed. In addition, the components described in the accompanying drawings and the detailed description may include components that are not essential for addressing problems. Therefore, just because these non-essential components are described in the accompanying drawings or the detailed description, it should not be recognized that these non-essential components are essential.

For example, the above embodiment may have the following structure.

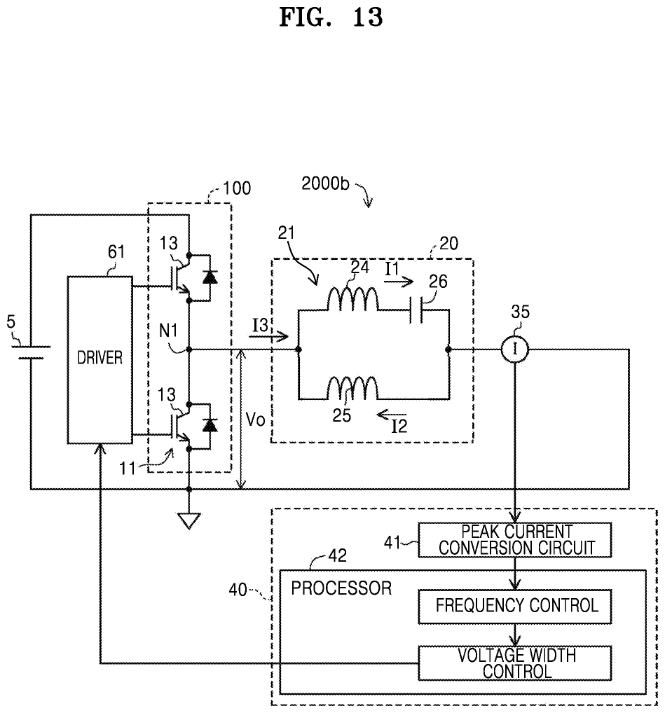

FIG. 13 is a circuit diagram of a heating device 2000b including a half-bridge inverter circuit, according to an embodiment of the disclosure.

In the previous embodiment, the inverter circuit 1 has been described as being a full-bridge inverter circuit. However, as shown in FIG. 13, the same effect as in the previous embodiment may be obtained even when a half-bridge inverter circuit 100 is used.

In the previous embodiment, other parallel resonance circuits may be used.

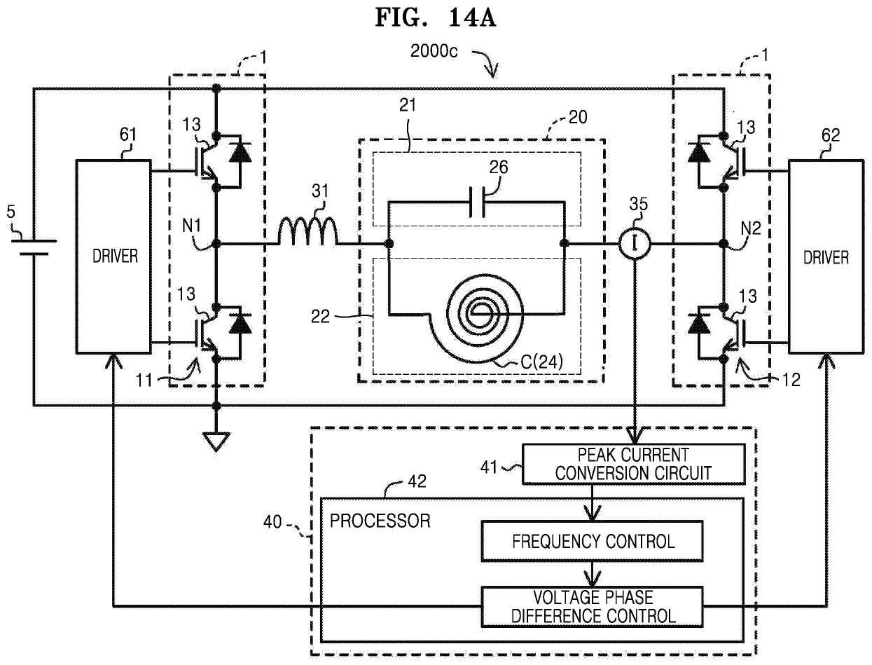

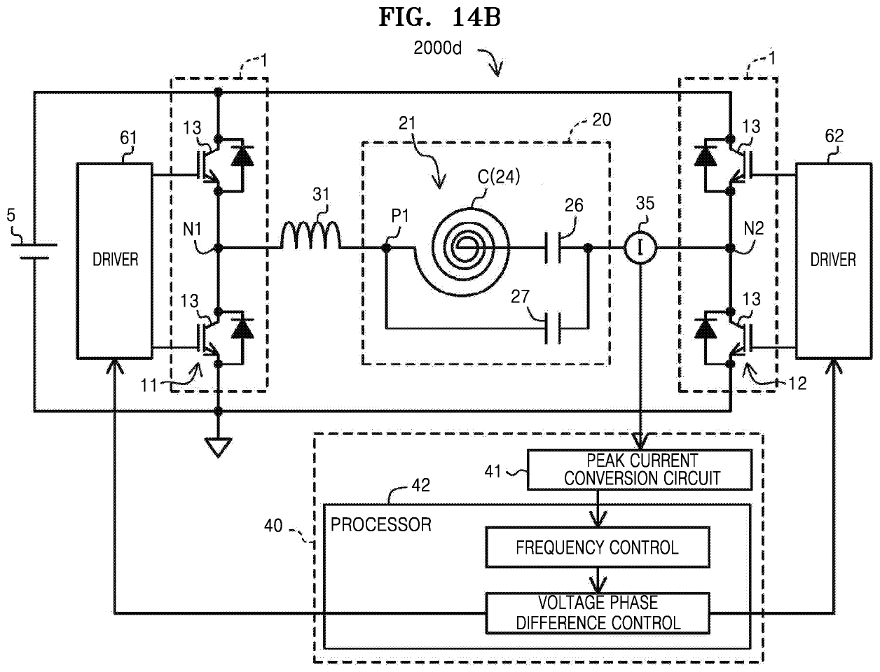

FIG. 14A is a circuit diagram of a heating device 2000c including a parallel resonance circuit, according to an embodiment of the disclosure.

For example, in FIG. 14A, a first circuit 21 of a parallel resonance circuit 20 may be composed of a resonance capacitor 26, and a second circuit 22 of the parallel resonance circuit 20 may be composed of an inductor 24 composed of a heating coil C.

FIG. 14B is a circuit diagram of a heating device 2000d including a parallel resonance circuit, according to another embodiment of the disclosure.

Referring to FIG. 14B, a first circuit 21 of a parallel resonance circuit 20 may be composed of the resonance capacitor 26 and the inductor 24 composed of the heating coil C, and a second circuit 22 of the parallel resonance circuit 20 may be composed of another resonance capacitor 27. As such, even when the parallel resonance circuit 20 varies, the technique according to the disclosure may be applied and the same effect may be obtained.

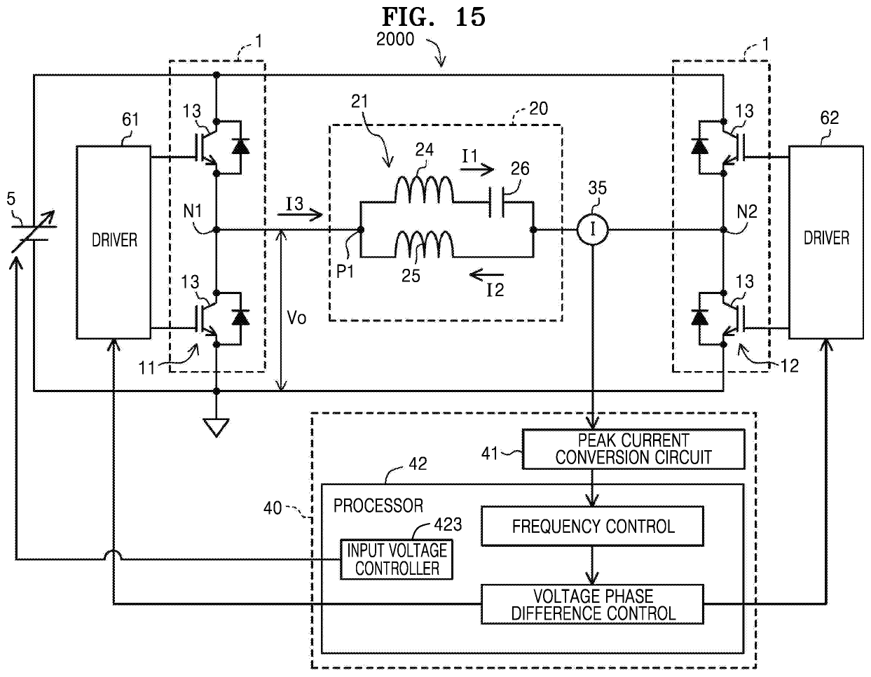

FIG. 15 is a circuit diagram of a heating device 2000 including a parallel resonance circuit when an input voltage of the inverter circuit 1 varies, according to an embodiment of the disclosure.

Referring to FIG. 15, the controller 40 includes an input voltage controller 423 that changes the input voltage Vi of the inverter circuit 1 according to the set amount of heat of the heating coil C. FIG. 15 illustrates an example in which the processor 42 functions as the input voltage controller 423. Accordingly, because the thermal power of the heating device 2000 may be controlled by maintaining the duty ratio of the output voltage Vo of the inverter circuit to be a large level and changing the input voltage in the input voltage controller 423, the thermal power may be widely controlled.

The peak current conversion circuits in the above embodiment may be included as a portion of the processor 42 according to another embodiment. In addition, the embodiments disclosed above in the disclosure may be used in combination with each other unless it is explicitly stated that they cannot be used in parallel with each other and in compatibility with each other.

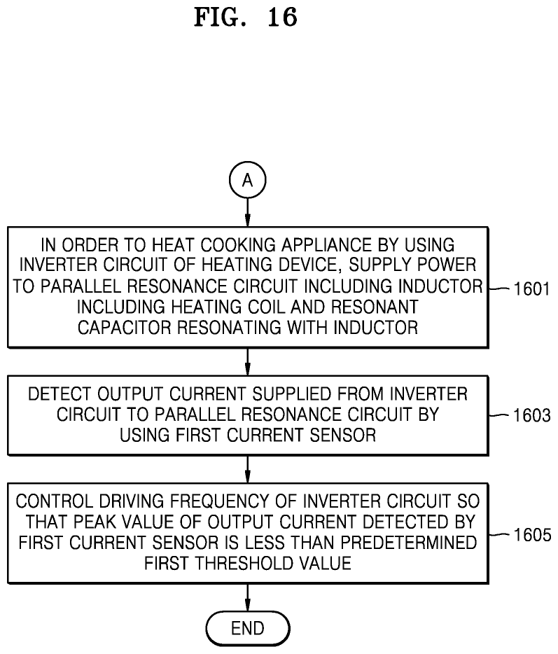

FIG. 16 is a flowchart of a method of controlling the heating device 2000, according to an embodiment of the disclosure.

In operation 1601, in order to heat the cooking appliance 10 by using the inverter circuit 1 of the heating device 2000, power is supplied to the resonance circuit including the inductor including the heating coil C and the resonance capacitor 26 resonating with the inductor.

In operation 1603, an output current supplied from the inverter circuit 1 to the parallel resonance circuit 20 is detected by the first current sensor 35.

In operation 1605, the controller 40 controls the driving frequency of the inverter circuit 1 so that the peak value of the output current detected by the first current sensor is less than a predetermined first threshold value.

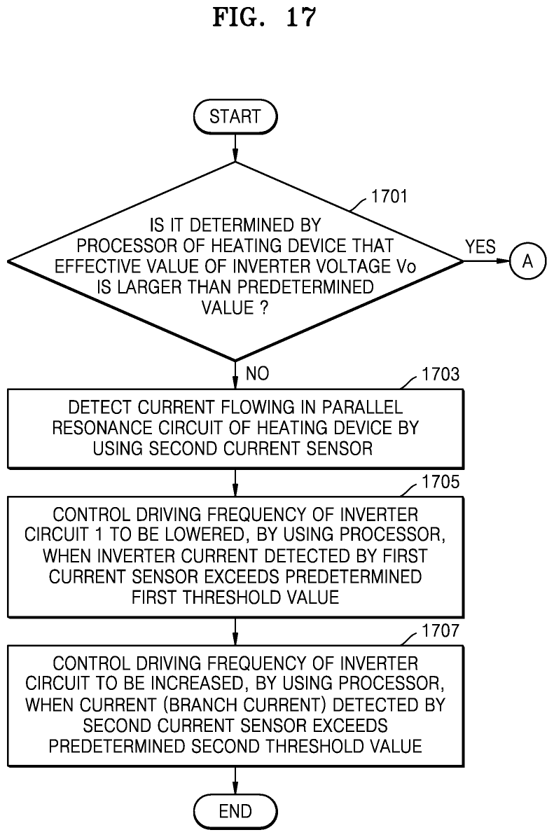

FIG. 17 is a flowchart of a method of controlling the heating device 2000, according to another embodiment of the disclosure.

First, in operation 1701, the processor 42 of the heating device 2000 determines whether the effective value of the inverter voltage Vo is large or small. At this time, whether the effective value of the inverter voltage Vo is large or small is determined by setting a predetermined value. For example, when the effective value of the inverter voltage Vo is 60% or more of the input voltage Vi of the inverter circuit 1, it may be determined that the effective value of the inverter voltage Vo is relatively large, and, when the effective value of the inverter voltage Vo is less than 60% of the input voltage Vi of the inverter circuit 1, it may be determined that the effective value of the inverter voltage Vo is relatively small. However, this is only an embodiment, and whether the effective value of the inverter voltage Vo is large or small based on the percentage % of the input voltage Vi of the inverter circuit 1 may vary according to designs.

When it is determined that the effective value of the inverter voltage Vo is large, control of the driving frequency control according to FIG. 16 is performed. On the other hand, when it is determined that the effective value of the inverter voltage Vo is small, the current flowing in the parallel resonance circuit 20 of the heating device 2000 is detected by the second current sensor 36, in operation 1703. In operation 1705, the processor 42 controls the driving frequency of the inverter circuit 1 to be lowered, when the inverter current I3 detected by the first current sensor 35 exceeds the predetermined first threshold value. In operation 1707, the processor 42 controls the driving frequency of the inverter circuit 1 to be increased, when a current (branch current) flowing in the parallel resonance circuit 20 detected by the second current sensor 36 exceeds the predetermined second threshold value, thereby performing resonance frequency tracking control.

A method according to an embodiment of the disclosure may be embodied as program commands executable by various computer means and may be recorded on a computer-readable recording medium. The computer-readable recording medium may include program commands, data files, data structures, and the like separately or in combinations. The program commands to be recorded on the computer-readable recording medium may be specially designed and configured for embodiments or may be well-known to and be usable by one of ordinary skill in the art of computer software. Examples of a computer-readable recording medium include a magnetic medium such as a hard disk, a floppy disk, or a magnetic tape, an optical medium such as a compact disk-read-only memory (CD-ROM) or a digital versatile disk (DVD), a magneto-optical medium such as a floptical disk, and a hardware device specially configured to store and execute program commands such as a ROM, a random-access memory (RAM), or a flash memory. Examples of the program commands are high-level language codes that can be executed by a computer by using an interpreter or the like as well as machine language codes made by a compiler.

An embodiment of the disclosure may also be implemented in the form of a recording medium including instructions executable by a computer, such as a program module executed by a computer. Computer-readable media may be any available media accessible by a computer and includes both volatile and nonvolatile media and removable and non-removable media. Further, the computer readable medium may include all computer storage and communication media. The computer storage medium includes all volatile/non-volatile and removable/non-removable media embodied by a certain method or technology for storing information such as computer readable instruction code, a data structure, a program module or other data. The communication medium typically includes the computer readable instruction code, the data structure, the program module, or other data of a modulated data signal, or other transmission mechanism, and includes any information transmission medium. An embodiment of the disclosure may be implemented as a computer program or a computer program product including instructions executable by a computer.

The machine-readable storage medium may be provided as a non-transitory storage medium. The ‘non-transitory storage medium’ is a tangible device and only means that it does not contain a signal (e.g., electromagnetic waves). This term does not distinguish a case in which data is stored semi-permanently in a storage medium from a case in which data is temporarily stored. For example, the non-transitory recording medium may include a buffer in which data is temporarily stored.

According to an embodiment of the disclosure, a method according to various disclosed embodiments may be provided by being included in a computer program product. The computer program product, which is a commodity, may be traded between sellers and buyers. Computer program products are distributed in the form of device-readable storage media (e.g., compact disc read only memory (CD-ROM)), or may be distributed (e.g., downloaded or uploaded) through an application store or between two user devices (e.g., smartphones) directly and online. In the case of online distribution, at least a portion of the computer program product (e.g., a downloadable app) may be stored at least temporarily in a device-readable storage medium, such as a memory of a manufacturer's server, a server of an application store, or a relay server, or may be temporarily generated.

1. A heating device comprising:
an inductor including a heating coil for heating a cooking appliance;
a parallel resonance circuit including the inductor, and a resonance capacitor resonating with the inductor;
an inverter unit for supplying power to the parallel resonance circuit;
a first current sensor for detecting an output current supplied from the inverter unit to the parallel resonance circuit; and
a processor for controlling a driving frequency of the inverter unit so that a peak value of the output current detected by the first current sensor is smaller than a predetermined first threshold value.

2. The heating device of claim 1, wherein the processor controls the driving frequency of the inverter unit in a direction in which a slope of the output current is decreased compared to a change in the driving frequency of the inverter unit.

3. The heating device of claim 1, further comprising an inductor filter for filtering a square wave voltage output from the inverter unit into a sine wave shape, the inductor filter disposed between the inverter unit and the parallel resonance circuit.

4. The heating device of claim 1, wherein the processor controls an input voltage of the inverter unit according to a set output heat amount of the heating coil.

5. The heating device of claim 1, wherein, based on a determination that an effective value of an output voltage of the inverter unit is greater than a predetermined value, the processor controls the driving frequency of the inverter unit so that the peak value of the output current detected by the first current sensor is smaller than the predetermined first threshold value.

6. The heating device of claim 1, further comprising a second current sensor for detecting a current flowing in the parallel resonance circuit,
wherein the processor controls the driving frequency of the inverter unit to decrease based on a determination that the peak value of the output current detected by the first current sensor is equal to or greater than the predetermined first threshold value, and controls the driving frequency of the inverter unit to increase when a peak value of a current detected by the second current sensor is greater than a predetermined second threshold value.

7. The heating device of claim 6, wherein the inverter unit is directly connected to the parallel resonance circuit.

8. The heating device of claim 6, wherein the second current sensor detects a current flowing in the inductor including the heating coil in the parallel resonance circuit.

9. The heating device of claim 6, wherein the second current sensor detects a current flowing in the resonance capacitor in the parallel resonance circuit.

10. The heating device of claim 6, wherein the processor controls the driving frequency of the inverter unit so that a peak value of a current flowing in a circuit including the heating coil and a peak value of a current flowing in a circuit including the resonance capacitor are within a predetermined error value.

11. The heating device of claim 1, wherein, based on a determination that a resonance frequency of the parallel resonance circuit changes due to the processor controlling the driving frequency of the inverter unit so that the peak value of the output current detected by the first current sensor is less than the predetermined first threshold value, the processor controls the driving frequency of the inverter unit to track the resonance frequency of the parallel resonance circuit.

12. The heating device of claim 1, wherein the resonance frequency of the parallel resonance circuit is changed by a change in a position of the cooking appliance placed on the heating device.

13. The heating device of claim 1, wherein a total impedance of the parallel resonance circuit is greater than an impedance of a circuit including the heating coil and greater than an impedance of a circuit including the resonance capacitor.

14. The heating device of claim 1, wherein the processor controls the driving frequency of the inverter unit in a state in which an effective value of input power of the inverter unit is fixed.

15. A method, performed by a heating device having a parallel resonance circuit including an inductor including a heating coil for heating a cooking appliance and a resonance capacitor resonating with the inductor, of tracking a resonance frequency, the method comprising:
supplying power, by an inverter unit included in the heating device, to the parallel resonance circuit;
detecting, by a first current sensor included in the heating device, an output current supplied from the inverter unit to the parallel resonance circuit; and
controlling, by a processor included in the heating device, a driving frequency of the inverter unit so that a peak value of the output current detected by the first current sensor is smaller than a predetermined first threshold value.

16. The method of claim 15, wherein the controlling of the driving frequency of the inverter unit comprises controlling the driving frequency of the inverter unit in a direction in which a slope of the output current is decreased compared to a change in the driving frequency of the inverter unit.

17. The method of claim 15, wherein the controlling of the driving frequency of the inverter unit comprises:
based on a determination that an effective value of an output voltage of the inverter unit is greater than a predetermined value, controlling the driving frequency of the inverter unit so that the peak value of the output current detected by the first current sensor is smaller than the predetermined first threshold value.

18. The method of claim 15, wherein the controlling of the driving frequency of the inverter unit comprises:
detecting, by a second current sensor, a current flowing in the parallel resonance circuit;
controlling the driving frequency of the inverter unit to decrease based on a determination that the peak value of the output current detected by the first current sensor is equal to or greater than the predetermined first threshold value; and
controlling the driving frequency of the inverter unit to increase when a peak value of a current detected by the second current sensor is greater than a predetermined second threshold value.

19. The method of claim 18, wherein the controlling of the driving frequency of the inverter unit comprises:
controlling the driving frequency of the inverter unit so that a peak value of a current flowing in a circuit including the heating coil and a peak value of a current flowing in a circuit including the resonance capacitor are within a predetermined error value.

20. The method of claim 15, further comprising
based on a determination that a resonance frequency of the parallel resonance circuit changes due to the controlling of the driving frequency of the inverter unit so that the peak value of the output current detected by the first current sensor is less than the predetermined first threshold value, controlling the driving frequency of the inverter unit to track the resonance frequency of the parallel resonance circuit.
